(19) United States
(12) Patent Application Publication
(10) Pub. No.: US 2021/0341557 A1
(43) Pub. Date: Nov. 4, 2021

(54) SYSTEMS AND METHODS FOR IMPROVED RECONSTRUCTION OF MAGNETIC RESONANCE FINGERPRINTING DATA WITH LOW-RANK METHODS

(71) Applicant: THE GENERAL HOSPITAL CORPORATION, Boston, MA (US)

(72) Inventors: Bo Zhao, Malden, MA (US); Lawrence Wald, Cambridge, MA (US)

(21) Appl. No.: 17/374,693

(22) Filed: Jul. 13, 2021

Related U.S. Application Data
(63) Continuation of application No. 15/419,385, filed on Jan. 30, 2017, now abandoned.
(60) Provisional application No. 62/293,805, filed on Feb. 11, 2016.

(51) Int. Cl. G01R 33/561; G01R 33/50

(52) U.S. Cl. CPC G01R 33/561; G01R 33/50

(57) ABSTRACT

Systems and methods for reconstructing MR parameter maps of a subject from magnetic resonance fingerprinting (MRF) data acquired using a magnetic resonance imaging (MRI) system. The method includes providing MRF data acquired from a subject using an MRI system and reconstructing the MRF data by solving a constrained optimization problem using a low-rank model, for which an input to the optimization problem is the MRF data and an output from the optimization problem is the MRF time-series images.

### CROSS-REFERENCE TO RELATED APPLICATIONS

This application is based on, claims priority to, and incorporates herein by reference in its entirety U.S. Provisional Application Ser. No. 62/293,805, filed Feb. 11, 2016, and entitled, “SYSTEMS AND METHODS FOR IMPROVED RECONSTRUCTION OF MAGNETIC RESONANCE FINGERPRINTING DATA WITH SUBSPACE METHODS.”

### STATEMENT REGARDING FEDERALLY SPONSORED RESEARCH

This invention was made with government support under R01EB017219 and R01EB017337 awarded by the National Institutes of Health. The government has certain rights in the invention.

### BACKGROUND

MRF is an imaging technique that enables quantitative mapping of tissue or other material properties. In particular, MRF can be conceptualized as employing a pulse sequence formed from series of varied “sub-blocks.” By varying parameters of the sub-blocks between respective sub-blocks that form the overall pulse sequence, the different signal evolutions from the different resonant species are elicited. The term “resonant species,” as used herein, refers to a material, such as water, fat, bone, muscle, soft tissue, and the like, that can be made to resonate using NMR. By way of illustration, when RF energy is applied to a volume that has both bone and muscle tissue, then the bone and muscle tissue will each produce an NMR signal. However the “bone signal” represents a first resonant species and the “muscle signal” represents a second resonant species and the two will be different. These different signals from different species can be collected simultaneously over a period of time to collect an overall “signal evolution” for the volume.

The random or pseudorandom measurements obtained in MRF techniques are achieved by varying the acquisition parameters from one repetition time (TR) period to the next, which creates a time series of images with varying contrast. Examples of acquisition parameters that can be varied include flip angle (FA), radio frequency (RF) pulse phase, TR, echo time (TE), and sampling patterns, such as by modifying one or more readout encoding gradients.

From these random or pseudorandom measurements, MRF processes can be designed to map any of a wide variety of parameters, such as longitudinal relaxation time (T₁), transverse relaxation time (T₂), main or static magnetic field map (B₀), and proton density (ρ). MRF is generally described in U.S. Pat. No. 8,723,518 and Published U.S. Patent Application No. 2015/0301141, each of which is incorporated herein by reference in its entirety.

The random or pseudorandom measurements obtained in MRF techniques are achieved by varying the acquisition parameters from one repetition time (“TR”) period to the next, which creates a time series of images with varying contrast. Examples of acquisition parameters that can be varied include flip angle, radio frequency (“RF”) pulse phase, TR, echo time (“TE”), and sampling patterns, such as by modifying one or more readout encoding gradients. Thus, the success of MRF is largely due to a specialized, incoherent acquisition scheme. More specifically, a sequence of randomized flip angles and repetition times (i.e., {(αₘ,TRₘ)}ₘ₌₁^{M}) is used to generate a sequence of images ({Iₘ(x)}ₘ₌₁^{M}) with randomly varied contrast weightings, yielding incoherence in the temporal domain. Moreover, a set of highly-undersampled variable density spiral trajectories can be used to acquire k-space data, which yields the spatial incoherence.

With these incoherently-sampled data, the conventional MRF reconstruction employs a template-matching procedure. Given a range of parameters of interest, the procedure uses a “dictionary” that contains all possible signal (or magnetization) evolutions simulated from the Bloch equation. That is, MRF matches an acquired magnetization signal to a pre-computed dictionary of signal evolutions, or templates, that have been generated from magnetic resonance signal models, such as Bloch equation-based physics simulations (i.e., Bloch simulations). As a general example, a template signal evolution is chosen from the dictionary if it yields the maximum correlation with the observed signal for each voxel (extracted from the gridding reconstructions). The parameters for the tissue or other material in a given voxel are estimated to be the values that provide the best signal template matching. That is, the reconstructed parameters are assigned as those that generate the selected template.

Although conventional MRF reconstruction procedures can be relatively robust in practice, there is no guarantee that MR tissue parameters of interest are reconstructed in an optimal manner. Furthermore, the original, straightforward template matching may not be computationally optimal, or even efficient. Recently, a number of new methods have been proposed to improve MRF reconstruction. Some have attempted to address the computational inefficiencies associated with the conventional MRF reconstruction. Others have proposed new iterative algorithms that leverage signal processing techniques, such as compressed sensing (“CS”), to improve reconstruction accuracy. Despite these efforts, MRF reconstruction continues to be a challenge, particularly when a large number of MR tissue parameters are considered in an MRF process.

### SUMMARY

The present disclosure overcomes the aforementioned drawbacks by providing a system and method for model-based magnetic resonance fingerprinting (MRF) reconstruction using a low-rank model that represents the MRF time-series images. This allows us to reconstruct an improved time-series of images which provides an improved input to the dictionary matching (or other parameter estimation approaches). Thus, the system and methods described herein yield substantial improvements in the accuracy of MRF reconstruction, compared to conventional MRF reconstruction techniques.

In accordance with one aspect of the disclosure, a magnetic resonance imaging (MRI) system is disclosed that includes a magnet system configured to generate a polarizing magnetic field about at least a portion of a subject arranged in the MRI system, a plurality of gradient coils configured to apply a gradient field to the polarizing magnetic field and a radio frequency (RF) system configured to apply an excitation field to the subject and acquire MR image data from a ROI. The system also includes a computer system programmed to control the plurality of gradient coils and the RF system to acquire magnetic resonance fingerprinting (MRF) data from a subject. The computer system is also programmed to reconstruct an MRF time series of images from the MRF data by solving a constrained optimization problem using a low-rank model, for which an input to the optimization problem is the MRF data and an output from the optimization problem is the MRF time-series images. The computer system is further programmed to estimate the MR parameter maps from the reconstructed time series of images.

In accordance with another aspect of the disclosure, a method is provided for reconstructing an image of a subject from magnetic resonance fingerprinting (MRF) data acquired using a magnetic resonance imaging (MRI) system. The method includes providing MRF data acquired from a subject using an MRI system and reconstructing the MRF data by solving a constrained optimization problem using a low-rank model, for which an input to the optimization problem is the MRF data and an output from the optimization problem is the MRF time-series images.

In accordance with another aspect of the disclosure, a method is provided for reconstructing an image of a subject from magnetic resonance fingerprinting (MRF) data acquired using a magnetic resonance imaging (MRI) system. The method includes providing MRF data acquired from a subject using an MRI system and reconstructing the MRF data by solving a constrained optimization problem using a low-rank model that represents the MRF data as a function of a spatial subspace and temporal subspace.

The foregoing and other aspects and advantages of the invention will appear from the following description. In the description, reference is made to the accompanying drawings that form a part hereof, and in which there is shown by way of illustration a preferred embodiment of the invention. Such embodiment does not necessarily represent the full scope of the invention, however, and reference is made therefore to the claims and herein for interpreting the scope of the invention.

### BRIEF DESCRIPTION OF THE DRAWINGS

FIG. 1 is a flowchart setting forth steps of a conventional magnetic resonance fingerprinting (MRF) reconstruction method.

FIG. 2 is a flow chart setting forth some example steps of a method for a MRF reconstruction process that enforces a low-rank model and subspace constraint and further allows for the integration of a joint sparsity constraint.

FIG. 3A is a set of images that compares reconstructed time series of images created using a conventional MRF reconstruction and a low-rank reconstruction in accordance with the present disclosure.

FIG. 3B is a set of images that compares reconstructed T1 maps and associated error maps created using a conventional MRF reconstruction and a low-rank reconstruction in accordance with the present disclosure.

FIG. 3C is a set of images that compares reconstructed T2 maps and associated error maps created using a conventional MRF reconstruction and a low-rank reconstruction in accordance with the present disclosure.

FIG. 3D is a set of images that compares reconstructed spin density maps and associated error maps created using a conventional MRF reconstruction and a low-rank reconstruction in accordance with the present disclosure.

FIG. 4 is a block diagram of an example of a magnetic resonance imaging (“MRI”) system configured for use in accordance with the present disclosure.

FIG. 5 is a block diagram of an example computer system that can be configured to implement the methods described herein.

### DETAILED DESCRIPTION

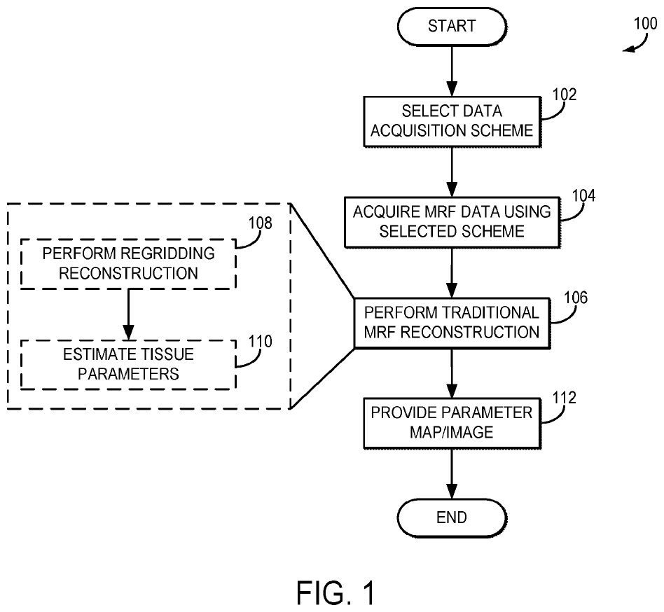

As described, magnetic resonance fingerprinting (“MRF”) techniques use varying acquisition parameters between repetition times (“TRs”) to creates a time series of images with varying contrast. Referring to FIG. 1, a conventional MRF process 100, at process block 102, begins by selecting a data acquisition scheme that causes signals from different materials or tissues to be spatially and temporally incoherent by continuously varying acquisition parameters throughout the data acquisition process. Examples of acquisition parameters that can be varied include flip angle, radio frequency (“RF”) pulse phase, repetition time (“TR”), echo time (“TE”), and sampling patterns, such as by modifying readout encoding gradients. Preferably, the acquisition parameters are varied in a pseudorandom manner.

At process block 104, MRF data is acquired using the acquisition scheme or parameters selected at process block 102. As a result of the spatial and temporal incoherence imparted by this acquisition scheme, each material or tissue is associated with a unique signal evolution or “fingerprint,” that is a function of multiple different physical parameters, including longitudinal relaxation time, T₁, transverse relaxation time, T₂, and proton density, ρ. As will be described, the present disclosure provides a framework for an iterative reconstruction process that may begin by selecting initial tissue parameters at process block 106.

In a conventional MRF process 106, a simple template-matching procedure is performed. In particular, such a conventional approach to MRF reconstruction first reconstructs a time-series of images by performing gridding reconstructions from highly-undersampled data (e.g., a spiral acquisition with 48× acceleration was originally used) at process block 108 to obtain a sequence of aliasing-artifact corrupted MRF time-series images. From the time-series images, the underlying tissue parameters are then estimated by comparison to a dictionary of signal evolutions at process block 110. Once the matching signal evolutions are identified at process block 110, MR tissue parameter maps are provided at process block 112. The degree of aliasing corruption in the time-series images demonstrates the potential to improve the method by replacing the simple gridding reconstruction with an advanced method to generate less artifact-corrupted images as an input to the dictionary matching step.

Conventional MRF reconstruction stops after such a reconstruction process 106. However, if used, this initial process only represents an initial selection of parameters because the present disclosure recognizes that the conventional MRF reconstruction process suffers from a number of key limitations. First, it is heuristic and statistically suboptimal, because the noise in the gridding reconstructions at process block 108 no longer follows a white Gaussian distribution. Such sub-optimality often leads to systematic bias in the subsequent parameter estimation at process block 110. Second, low-quality MRF time series from the gridding reconstructions make the accuracy of tissue parameter estimation at process block 110 heavily dependent on the length of data acquisition, especially for certain parameters, such as T₂. Achieving accurate estimates of tissue parameters often requires a relatively long acquisition sequence. Third, the conventional approach 108 is only integrated with multichannel acquisition in an ad-hoc way, which does not fully exploit the SNR benefit offered by the phased array coils.

As described, to overcome the shortcomings of conventional MRF reconstruction, a prior image model can be incorporated into the reconstruction process to improve the accuracy of the reconstruction process. Thus, the reconstruction process described with respect to FIG. 1 can be changed to incorporate a model-based approach that uses joint low-rank and sparse structure to improve the reconstructions of the MRF time series. Thus, the tissue parameter maps created at process block 120 can be derived from an improved time series using the dictionary matching, which substantially improves the accuracy of the time-series image reconstruction.

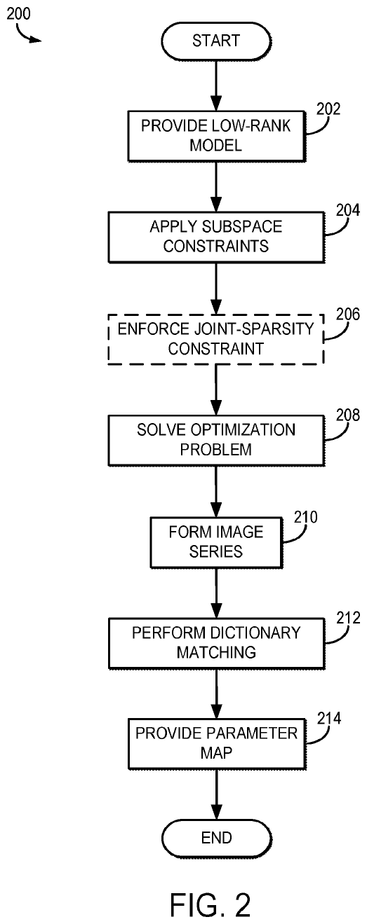

In particular, referring to FIG. 2 a general reconstruction process 200 will be described. The process 200, as will be described, leverages a low-rank modeling to capture the strong correlations among the MRF time series images. More specifically, an explicit low-rank constraint is employed via matrix factorization to dramatically reduce the number of degrees of freedom for image reconstruction.

Specifically, let Cϵ [symbol] ^{N×M} denote the Casorati matrix (for example, as described in, Z.-P. Liang, “Spatioteporal imaging with partially separable functions”, B. Zhao, J. P. Haldar, C. Brinegar, and Z.-P. Liang, “Low rank matrix recovery for real-time cardiac MRI,” IEEE Int. Symp. Biomed. Imaging, pp. 996-999, 2010., which is incorporated herein in its entirety. In this context, C represents a time-series image associated with an MRF experiment, which as a non-limiting example may be a contrast-weighted image sequence. Due to the strong spatiotemporal correlation of images, a low-rank model is introduced at process block 202 to represent C . That is, C=UV, where Uϵ [symbol] ^{N×L} and Vϵ [symbol] ^{L×M} respectively denote the spatial and temporal subspaces of C, and L denotes the rank.

At process block 204, the temporal subspace structure of the low-lank model is pre-estimated from an ensemble of magnetization dynamics. This provides additional subspace constraint to improve the conditioning of the inverse problems. For example, the temporal subspace may be pre-estimated for the low-rank model, denoted as \hat{V}, from the ensemble of magnetization dynamics using the principal component analysis, such as described in the above-referenced “Spatioteporal imaging with partially separable functions,” or A. S. Gupta and Z. -P. Liang, “Dynamic imaging by temporal modeling with principle component analysis”, Proc. Int. Symp. Magn. Reson. Med., p. 10, 2001; C. Huang, C. G. Graff, E. W. Clarkson, A. Belgin, and M. I. Altbach, “T2 mapping from highly undersampled data by reconstruction of principal component coefficient maps using compressed sensing”. Magn. Reson. Med., vol. 67, pp. 1355-1366, 2012; or J. P. Haldar and Z.-P. Liang, “Spatiotemporal imaging with partially separable functions: a matrix recovery approach”, IEEE Int. Symp. Biomed. Imaging, pp. 716-719, 2010, each of which is incorporated herein by reference in its entirety. Additionally, at process block 206, a joint sparsity constraint can be further incorporated to capture correlated edge structure of co-registered images, regularizing any ill-conditioned low-rank reconstruction. See B. Zhao, J. P. Haldar, and Z.-P. Liang, “PSF model-based reconstruction with sparsity constraint: Algorithm and application to real-time cardiac MRI”, 32nd Annual International Conference of the IEEE Engineering in Medicine and Biology, pp. 996-999, 2010.; B. Zhao, J. P. Haldar, A. G. Christodoulou, and Z.-P. Liang, “Further development of image reconstruction from highly-undersampled (k, t)-space data with joint partial separability and sparsity constraints”, IEEE Int. Symp. Biomed. Imaging, pp. 1593-1596, 2011.; and B. Zhao, J. P. Haldar, A. G. Christodoulou, and Z.-P. Liang, “Image reconstruction from highly undersampled (k, t)-space data with joint partial separability and sparsity constraints,” IEEE Trans. Medical Imaging, vol. 31, pp. 1809-1820, 2012., each of which is incorporated herein by reference in its entirety.

Putting together the above constraints, the reconstruction problem can be formulated as:

$$\hat{U} = arg {min}_{U} {\sum }_{c = 1}^{{N}_{C}} {‖ {d}_{c} - {F}_{u} {S}_{c} U \hat{V} ‖}_{2}^{2} + λ {‖ DU \hat{V} ‖}_{1 , 2} ; \qquad Eqn . 24$$

where d_{c} denotes the acquired k-space data for the c^{th} coil, Fᵤ is the undersampled Fourier encoding matrix, S_{c} is the coil sensitivities associated with the c^{th} coil, D is the spatial finite difference matrix, and λ is a regularization parameter. This formulation results in a convex optimization problem, which can be solved at process block 208 by applying an augmented Lagrangian-based method, or as one non-limiting example, an alternating direction method of multipliers (ADMM) algorithm, such as described in S. Ramani and J. A. Fessler, “Parallel MR image reconstruction using augmented Lagrangian methods”, IEEE Trans. Med. Imaging., vol. 30, pp. 694-706, 2011, which is incorporated herein by reference in its entirety. Thus, with the reconstructed spatial subspace Û, Ĉ=Û\hat{V} can be formed at process block 210, from which the dictionary matching can be performed at process block 212 to then deliver the desired parameter map at process block 214.

The process described with respect to FIG. 2 may be used to improve the accuracy of conventional MRF reconstruction. This stands in stark contrast to other methods or attempts to use low-rank/subspace models to simply compress the dictionary before performing a gridding reconstruction. That is, such attempts to simply compress a dataset to reduce the complexity of MRF reconstruction are fundamentally different from the above-described process that uses the low-rank model to solve an inverse problem involved in MRF time-series image reconstruction. See D. McGivney, E. Pierre, D. Ma, Y. Jiang, H. Saybasili, V. Gulani, M. A. Griswold, “SVD compression for magnetic resonance fingerprinting in the time domain”, IEEE Tran. Medical Imaging, vol. 33, pp 2311-2322, 2014., which is incorporated herein by reference in its entirety. The above-described process provides a model-based approach that uses low-rank and sparsity constraints to improve the quality of MRF reconstruction by providing more accurate tissue parameter maps compared to conventional MRF reconstructions.

More particularly, as described above, conventional MR image reconstruction, first performs gridding reconstructions from highly-undersampled spiral data (with 48× acceleration) to obtain a sequence of aliasing-artifact corrupted MRF time series images. Then, conventional MR image reconstruction estimates the underlying tissue parameters from the time series images. This approach has a number of key limitations. First, low-quality MRF time series obtained by the gridding reconstructions make the accuracy of tissue parameters heavily dependent on the length of data acquisition. The issue is particularly severe for the T2 map. To obtain accurate and robust estimates of tissue parameters, relatively long acquisition sequence is often needed. Second, gridding reconstructions of highly undersampled data often suffer from limited SNR (especially-for high resolution applications). This can fundamentally impact the accuracy of the subsequent parameter estimation.

However, the process described above with respect to FIG. 2 provides a new model-based iterative reconstruction method based on low-rank/subspace modeling to reconstruct high-quality MRF time-series images. These images can then be used for subsequent tissue parameter estimation. In one non-limiting example, the process described above with respect to FIG. 2 was utilized for in vivo MRF experiments. In this non-limiting study, a 2D in vivo MRF experiment was performed on a 3T Siemens scanner with a 32 channel head coils using an identical IR FISP sequence, spiral trajectory, and flip angles and TRs as described in Y. Jiang, D. Ma, N. Seiberlich, V. Gulani, and M. A. Griswold, “MR fingerprinting using fast imaging with steady state free precession (FISP) with spiral readout”, Magn. Reson. Med., 2015. The acquisition parameters included: FOV=300×300 mm², matrix size=256×256, and slice thickness of 5 mm. For each acquisition parameter a single spiral interleave was used (the fully sampled data required 48 interleaves). Data were acquired with 1000 TRs (i.e., corresponding to the duration of 13.1 s) to obtain a set of sparsely-sampled data for image reconstruction. To obtain a fully sampled “gold standard” for comparison, the above experiment was repeated 48 times, rotating the spiral trajectory. For the sparsely-sampled data, the conventional MRF reconstruction, and the process described with respect to FIG. 2 was performed. For the process described with respect to FIG. 2, the model order and regularization parameter were empirically chosen for optimized performance.

Comparisons of the MRF time series reconstructions from the conventional MRF (gridding reconstruction) and the process described with respect to FIG. 2 showed distinct improvements using the process described with respect to FIG. 2. For example, as opposed to the results created using the conventional MRF reconstruction, which estimates parameter maps from the artifact-corrupted gridding reconstruction, the proposed method provides higher quality images for subsequent parameter estimation.

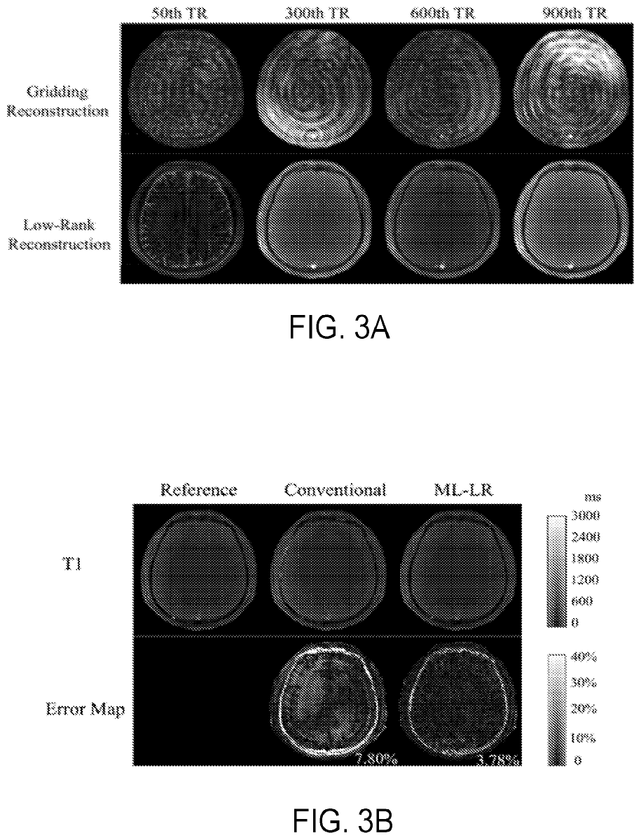

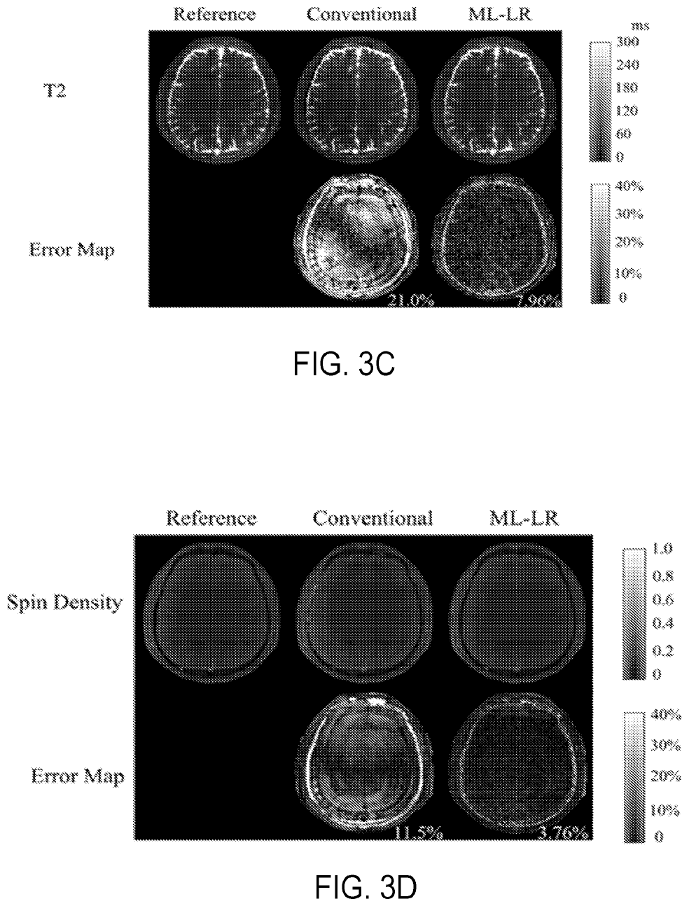

Specifically, referring to FIG. 3A, a set of images is provided that compares reconstructed MRF time series images with a 48× accelerated spiral acquisition using the gridding reconstruction, and the low-rank reconstruction technique described above with respect to FIG. 2. As opposed to the images created using the conventional approach, which estimates parameter maps from artifacts corrupted gridding reconstruction, the low-rank reconstruction described above with respect to FIG. 2 yields significantly better contrast-weighted time-series images for subsequent parameter estimation.

Also, referring to FIG. 3B, a set of images is provided that compares reconstructed T1 maps and associated error maps. The T1 maps include a reference map, a T1 map created using the conventional MRF reconstruction, and a T1 map created using the approach described above with respect to FIG. 2. Also, the error maps include a reference error map, an error map created using the conventional MRF approach, and an error map created using the approach described above with respect to FIG. 2. Here the reference T1 map is treated as the underlying “gold standard”, for which the reconstruction error is assumed to be zero. As clearly shown, the results provided for both the T1 map and the error map in FIG. 3B are superior to those created using the conventional method.

Furthermore, referring to FIG. 3C, a set of images is provided that compares reconstructed T2 maps and associated error maps. The T2 maps include a reference map, a T2 map created using the conventional MRF reconstruction, and a T2 map created using the approach described above with respect to FIG. 2. Also, the error maps include a reference error map, an error map created using the conventional MRF approach, and an error map created using the approach described above with respect to FIG. 2. Here the reference T2 map is treated as the underlying “gold standard”, for which the reconstruction error is assumed to be zero. As clearly shown, the results provided for both the T2 map and the error map in FIG. 3C are superior to those created using the conventional method.

Finally, referring to FIG. 3D, a set of images is provided that compares reconstructed spin density maps and associated error maps. The spin density maps include a reference map, a spin density map created using the conventional MRF reconstruction, and a spin density map created using the approach described above with respect to FIG. 2. Also, the error maps include a reference error map, a spin density error map created using the conventional MRF approach, and a spin density error map created using the approach described above with respect to FIG. 2. Here the reference spin density map is treated as the underlying “gold standard”, for which the reconstruction error is assumed to be zero. As clearly shown, the results provided for both the spin density map and the error map in FIG. 3D are superior to those created using the conventional methods.

The above-described technique employs an explicit low-rank constraint via matrix factorization, which efficiently captures the underlying spatiotemporal correlation of MRF time series images. This leads to a dramatic reduction in the number of degree-of-freedom for image reconstruction, making it possible to achieve high-quality reconstructions from a 48× accelerated spiral acquisitions.

The proposed technique has been integrated parallel MR imaging with phased array coils to enable even faster imaging speed and/or higher SNR. The algorithm has a highly parallel structure, making it well suited to distributed computing. As described above, the proposed mathematical formulation results in a convex optimization problem, for which a globally convergent algorithm based on the augmented Lagrangian-based method can be used.

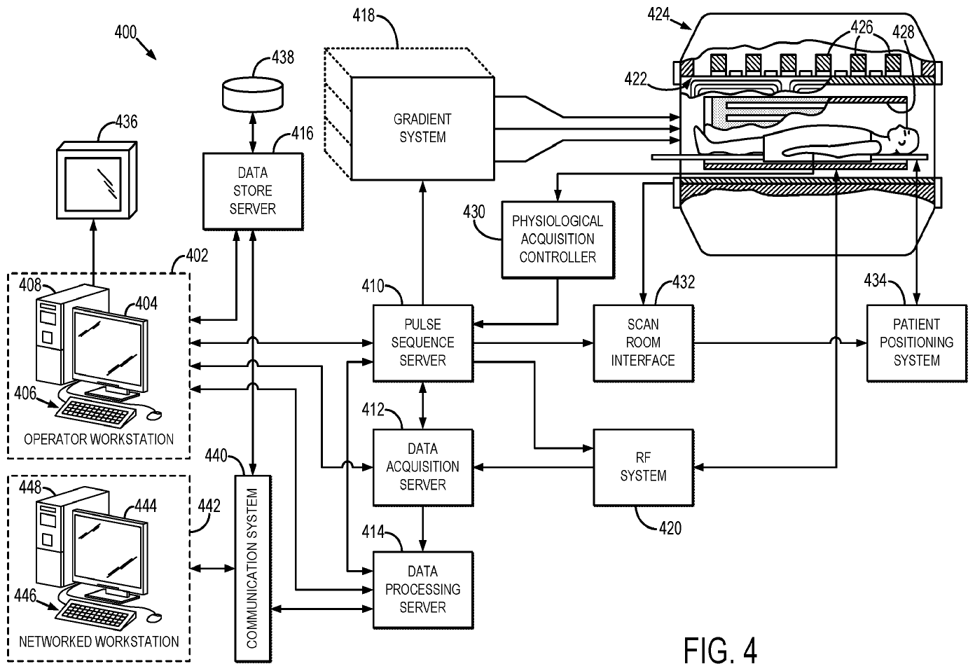

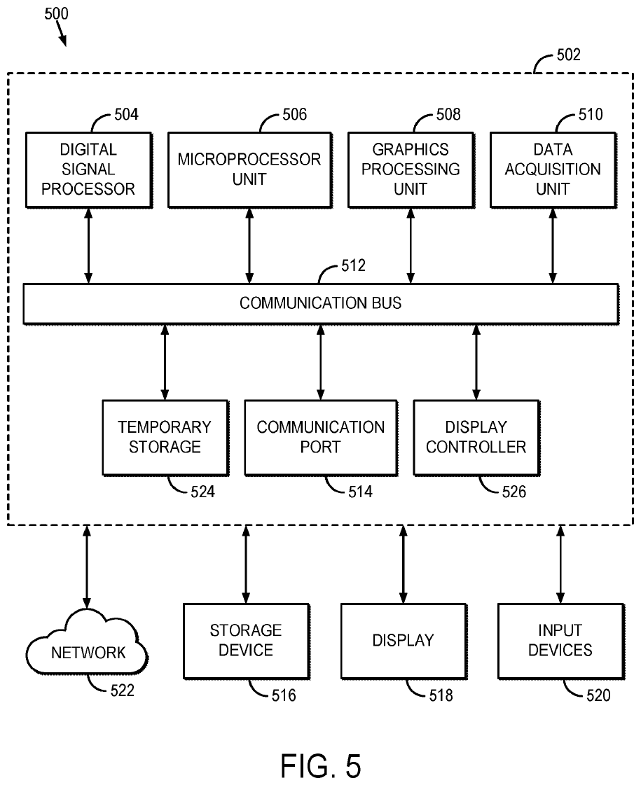

Referring now to FIG. 4, the above-described systems and methods may be implemented using or designed to accompany a magnetic resonance imaging (“MRI”) system 400, such as is illustrated in FIG. 4. The MRI system 400 includes an operator workstation 402, which will typically include a display 404, one or more input devices 406 (such as a keyboard and mouse or the like), and a processor 408. The processor 408 may include a commercially available programmable machine running a commercially available operating system. The operator workstation 402 provides the operator interface that enables scan prescriptions to be entered into the MRI system 400. In general, the operator workstation 402 may be coupled to multiple servers, including a pulse sequence server 410; a data acquisition server 412; a data processing server 414; and a data store server 416. The operator workstation 402 and each server 410, 412, 414, and 416 are connected to communicate with each other. For example, the servers 410, 412, 414, and 416 may be connected via a communication system 440, which may include any suitable network connection, whether wired, wireless, or a combination of both. As an example, the communication system 440 may include both proprietary or dedicated networks, as well as open networks, such as the internet.

The pulse sequence server 410 functions in response to instructions downloaded from the operator workstation 402 to operate a gradient system 418 and a radiofrequency (“RF”) system 420. Gradient waveforms to perform the prescribed scan are produced and applied to the gradient system 418, which excites gradient coils in an assembly 422 to produce the magnetic field gradients Gₓ, G_{y}, G_{z} used for position encoding magnetic resonance signals. The gradient coil assembly 422 forms part of a magnet assembly 424 that includes a polarizing magnet 426 and a whole-body RF coil 428.

RF waveforms are applied by the RF system 420 to the RF coil 428, or a separate local coil (not shown in FIG. 4), in order to perform the prescribed magnetic resonance pulse sequence. Responsive magnetic resonance signals detected by the RF coil 428, or a separate local coil, are received by the RF system 420, where they are amplified, demodulated, filtered, and digitized under direction of commands produced by the pulse sequence server 410. The RF system 420 includes an RF transmitter for producing a wide variety of RF pulses used in MRI pulse sequences. The RF transmitter is responsive to the scan prescription and direction from the pulse sequence server 410 to produce RF pulses of the desired frequency, phase, and pulse amplitude waveform. The generated RF pulses may be applied to the whole-body RF coil 428 or to one or more local coils or coil arrays.

The RF system 420 also includes one or more RF receiver channels. Each RF receiver channel includes an RF preamplifier that amplifies the magnetic resonance signal received by the coil 428 to which it is connected, and a detector that detects and digitizes the I and Q quadrature components of the received magnetic resonance signal. The magnitude of the received magnetic resonance signal may, therefore, be determined at any sampled point by the square root of the sum of the squares of the I and Q components:

M=\sqrt{I²+Q²} Eqn. 25;

and the phase of the received magnetic resonance signal may also be determined according to the following relationship:

$$ϕ = {tan}^{- 1} ( \frac{Q}{I} ) . \qquad Eqn . 26$$

The pulse sequence server 410 also optionally receives patient data from a physiological acquisition controller 430. By way of example, the physiological acquisition controller 430 may receive signals from a number of different sensors connected to the patient, such as electrocardiograph (“ECG”) signals from electrodes, or respiratory signals from a respiratory bellows or other respiratory monitoring device. Such signals are typically used by the pulse sequence server 410 to synchronize, or “gate,” the performance of the scan with the subject's heart beat or respiration.

The pulse sequence server 410 also connects to a scan room interface circuit 432 that receives signals from various sensors associated with the condition of the patient and the magnet system. It is also through the scan room interface circuit 432 that a patient positioning system 434 receives commands to move the patient to desired positions during the scan.

The digitized magnetic resonance signal samples produced by the RF system 420 are received by the data acquisition server 412. The data acquisition server 412 operates in response to instructions downloaded from the operator workstation 402 to receive the real-time magnetic resonance data and provide buffer storage, such that no data is lost by data overrun. In some scans, the data acquisition server 412 does little more than pass the acquired magnetic resonance data to the data processor server 414. However, in scans that require information derived from acquired magnetic resonance data to control the further performance of the scan, the data acquisition server 412 is programmed to produce such information and convey it to the pulse sequence server 410. For example, during prescans, magnetic resonance data is acquired and used to calibrate the pulse sequence performed by the pulse sequence server 410. As another example, navigator signals may be acquired and used to adjust the operating parameters of the RF system 420 or the gradient system 418, or to control the view order in which k-space is sampled. In still another example, the data acquisition server 412 may also be employed to process magnetic resonance signals used to detect the arrival of a contrast agent in a magnetic resonance angiography (“MRA”) scan. By way of example, the data acquisition server 412 acquires magnetic resonance data and processes it in real-time to produce information that is used to control the scan.

The data processing server 414 receives magnetic resonance data from the data acquisition server 412 and processes it in accordance with instructions downloaded from the operator workstation 402. Such processing may, for example, include one or more of the following: reconstructing two-dimensional or three-dimensional images by performing a Fourier transformation of raw k-space data; performing other image reconstruction techniques, such as iterative or backprojection reconstruction techniques; applying filters to raw k-space data or to reconstructed images; generating functional magnetic resonance images; calculating motion or flow images; and so on.

Images reconstructed by the data processing server 414 are conveyed back to the operator workstation 402. Images may be output to operator display 412 or a display 436 that is located near the magnet assembly 424 for use by attending clinician. Batch mode images or selected real time images are stored in a host database on disc storage 438. When such images have been reconstructed and transferred to storage, the data processing server 414 notifies the data store server 416 on the operator workstation 402. The operator workstation 402 may be used by an operator to archive the images, produce films, or send the images via a network to other facilities.

The MRI system 400 may also include one or more networked workstations 442. By way of example, a networked workstation 442 may include a display 444, one or more input devices 446 (such as a keyboard and mouse or the like), and a processor 448. The networked workstation 442 may be located within the same facility as the operator workstation 402, or in a different facility, such as a different healthcare institution or clinic. The networked workstation 442 may include a mobile device, including phones or tablets.

The networked workstation 442, whether within the same facility or in a different facility as the operator workstation 402, may gain remote access to the data processing server 414 or data store server 416 via the communication system 440. Accordingly, multiple networked workstations 442 may have access to the data processing server 414 and the data store server 416. In this manner, magnetic resonance data, reconstructed images, or other data may exchanged between the data processing server 414 or the data store server 416 and the networked workstations 442, such that the data or images may be remotely processed by a networked workstation 442. This data may be exchanged in any suitable format, such as in accordance with the transmission control protocol (“TCP”), the internet protocol (“IP”), or other known or suitable protocols.

Beyond the above-described MRI system, the systems and methods described herein may be performed using a computer system that is separate from an MRI system that is used to acquire imaging or MRF data. Referring now to FIG. 5, a block diagram of an example computer system 500 that can be configured to reconstruct magnetic resonance images using a ML-MRF reconstruction process, as described above, is illustrated. The data from which the magnetic resonance images are reconstructed can be provided to the computer system 500 from the respective MRI system and received in a processing unit 502.

In some configurations, the processing unit 502 can include one or more processors. As an example, the processing unit 502 may include one or more of a digital signal processor (“DSP”) 504, a microprocessor unit (“MPU”) 506, and a graphics processing unit (“GPU”) 508. The processing unit 502 can also include a data acquisition unit 510 that is configured to electronically receive data to be processed, which may include magnetic resonance image data. The DSP 504, MPU 506, GPU 508, and data acquisition unit 510 are all coupled to a communication bus 512. As an example, the communication bus 512 can be a group of wires, or a hardwire used for switching data between the peripherals or between any component in the processing unit 502.

The DSP 504 can be configured to receive and processes the magnetic resonance data or reconstructed magnetic resonance images. The MPU 506 and GPU 508 can also be configured to process the magnetic resonance data or reconstructed magnetic resonance images in conjunction with the DSP 504. As an example, the MPU 506 can be configured to control the operation of components in the processing unit 502 and can include instructions to perform reconstruction of the magnetic resonance image data on the DSP 504. Also as an example, the GPU 508 can process image graphics.

In some configurations, the DSP 504 can be configured to process the magnetic resonance image data received by the processing unit 502 in accordance with the techniques described above. Thus, the DSP 504 can be configured to reconstruct magnetic resonance images or MRF images using the described above ML-MRF process.

The processing unit 502 preferably includes a communication port 514 in electronic communication with other devices, which may include a storage device 516, a display 518, and one or more input devices 520. Examples of an input device 520 include, but are not limited to, a keyboard, a mouse, and a touch screen through which a user can provide an input.

The storage device 516 is configured to store images, whether provided to or processed by the processing unit 502. The display 518 is used to display images, such as images that may be stored in the storage device 516, and other information. Thus, in some configurations, the storage device 516 and the display 518 can be used for displaying reconstructed magnetic resonance images.

The processing unit 502 can also be in electronic communication with a network 522 to transmit and receive data, including CT images, MR images, and other information. The communication port 514 can also be coupled to the processing unit 502 through a switched central resource, for example the communication bus 512.

The processing unit 502 can also include a temporary storage 524 and a display controller 526. As an example, the temporary storage 524 can store temporary information. For instance, the temporary storage 524 can be a random access memory.

The present invention has been described in terms of one or more preferred embodiments, and it should be appreciated that many equivalents, alternatives, variations, and modifications, aside from those expressly stated, are possible and within the scope of the invention.

1-20. (canceled)

21. A magnetic resonance imaging (MM) system comprising:
a magnet system configured to generate a polarizing magnetic field about at least a portion of a subject arranged in the MM system;
a plurality of gradient coils configured to apply a gradient field to the polarizing magnetic field;
a radio frequency (RF) system configured to apply an excitation field to the subject and acquire MR image data from a ROI;
a computer system programmed to:
access a low-rank model;
apply subspace constraints for the low-rank model, wherein the temporal subspace structure of the low-lank model is pre-estimated from an ensemble of magnetization dynamics;
control the plurality of gradient coils and the RF system to acquire magnetic resonance fingerprinting (MRF) data from a subject;
reconstruct an MRF time series of images from the MF data by solving a constrained optimization problem using the low-rank model and the subspace constraints, for which an input to the optimization problem is the MRF data and an output from the optimization problem is the MRF time-series images; and
generate MR parameter maps from the reconstructed time series of images.

22. The system of claim 21 wherein the computer is further programmed to apply the subspace constraints for the low-rank model by estimating a temporal subspace structure of the low-rank model from an ensemble of magnetization dynamics.

23. The system of claim 21 wherein the computer is further programmed to apply the subspace constraints using a matrix factorization to reduce a number of degrees of freedom for reconstructing the MRF time-series of images.

24. The system of claim 21 wherein the computer is further programmed to select initial tissue parameters reconstructing the MRF time-series of images and iteratively adjust the tissue parameters by solving the optimization problem.

25. The system of claim 21 wherein the computer is further programmed to combine a joint sparsity constraint that captures correlated edge structure of co-registered MRF time-series images.

26. A method for reconstructing MR parameter maps from magnetic resonance fingerprinting (MRF) data acquired using a magnetic resonance imaging (MRI) system, the method carried out by a computer system programmed to carry out the method comprising:
accessing a low-rank model;
applying subspace constraints for the low-rank model, wherein the temporal subspace structure of the low-lank model is pre-estimated from an ensemble of magnetization dynamics;
accessing magnetic resonance fingerprinting (MRF) data of a subject;
reconstructing an MRF time series of images from the MF data by solving a constrained optimization problem using the low-rank model and the subspace constraints, for which an input to the optimization problem is the MRF data and an output from the optimization problem is the MRF time-series images; and
generating MR parameter maps from the reconstructed time series of images.

27. The method of claim 26 wherein the computer is further programmed to apply the subspace constraints for the low-rank model by estimating a temporal subspace structure of the low-rank model from an ensemble of magnetization dynamics.

28. The method of claim 26 wherein the computer is further programmed to apply the subspace constraints using a matrix factorization to reduce a number of degrees of freedom for reconstructing the MRF time-series of images.

29. The method of claim 26 wherein the computer is further programmed to select initial tissue parameters reconstructing the MRF time-series of images and iteratively adjust the tissue parameters by solving the optimization problem.

30. The method of claim 26 wherein the computer is further programmed to perform an augmented Lagrangian-based method to solve the optimization problem.

31. The method of claim 26 wherein the computer is further programmed to perform a dictionary matching process to generate MR parameter maps from the MRF data.

32. The method of claim 26 wherein the optimization problem is formed as:
C=UV;
where C represents the collection of MRF time-series images, Uϵ [symbol] ^{N×L} and Vϵ [symbol] ^{L×N} respectively represent spatial and temporal subspaces of C, L denotes a rank value, and M and N respectively represent the row and column dimensions of the matrix C.

33. The method of claim 32 wherein, to solve the constrained optimization problem, the spatial subspace, Û is found by:
$$\hat{U} = arg {min}_{U} {\sum }_{c = 1}^{{N}_{C}} {‖ {d}_{c} - {F}_{u} {S}_{c} U \hat{V} ‖}_{2}^{2} + λ {‖ DU \hat{V} ‖}_{1 , 2}$$
where d_{c} represents MRF data from the c^{th} coil, Fᵤ represents an undersampled Fourier encoding matrix, S_{c} represents coil sensitivities associated with the c^{th} coil, D represents a spatial finite difference matrix, and λ represents a regularization parameter.
